(19) United States
(12) Patent Application Publication
(10) Pub. No.: US 2004/0166444 A1
(43) Pub. Date: Aug. 26, 2004

(54) Method of producing substrate with mark, program for reading mark, and apparatus for reading mark

(75) Inventor: Shigeo Kiso, Nara (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/781,693

(22) Filed: Feb. 20, 2004

(30) Foreign Application Priority Data
Feb. 25, 2003 (JP) 2003-046660

(51) Int. Cl. G11B 11/00

(52) U.S. Cl. 430/311

(57) ABSTRACT

A method of producing a substrate with marks is provided in which a method of forming marks nonparallel to the direction of generation of a factor that hinders reading and a method of forming marks while offsetting marking positions in a direction perpendicular to the direction of generation of the factor of hindrance are combined to enable the consecutive marks to have different portions subjected to hindrance to reading, and the results of reading of the marks are compared with each other to perform processing for complementation of the portion subjected to the hindrance.

### BACKGROUND OF THE INVENTION

1. Field of the Invention

The present invention relates to a method of producing a substrate, e.g., a photovoltaic element substrate to which a mark for management in a production process is attached, a program for reading the mark, and a reading apparatus having the reading program incorporated therein.

2. Related Background Art

Photovoltaic elements are used in solar cell modules and attract attention as a clean energy source. The current challenge for producers of photovoltaic elements is to reduce the production cost.

As a method of producing photovoltaic elements in a large amount at a low cost, a method called a roll-to-roll system is known. In this system, a photovoltaic element is produced by successively forming films as a back surface electrode layer, semiconductor layer and a surface electrode layer on a continuous substrate in a roll form, e.g., a non-light transmissive stainless steel roll while the substrate is being unrolled and transported (or moved). The photovoltaic element made by these film formation steps and rerolled is cut into pieces of a certain length and processed in subsequent steps to be obtained as elements in a sheet-shaped state (cells). These cells undergo mounting, a series connection step, a resin encapsulation step, etc., to form a solar cell module.

A solar cell module is fabricated by a plurality of process steps as described above. To fabricate a solar cell module so that the most important device, i.e., the photovoltaic element, in particular, is uniform in output characteristics in terms of performance and quality, control of production conditions in each film formation step is required.

As a method for such production condition control, a method of attaching a bar code, an ID number or the like to a product to manage a processing history is being generally practiced. For example, Japanese Patent Application Laid-Open No. 2001-102604 discloses a method of controlling a process of fabricating a photoelectric conversion device by attaching a mark for control of the production process to a light transmissive substrate and reading the mark in subsequent production steps.

Japanese Patent Application Laid-Open No. H7-283431 discloses a production process control method including collecting, in a process of producing an article by using a continuous member as a raw material, data indicating the positions of occurrence of production defects in the continuous member due to an abnormality of a production apparatus, a process abnormality, etc. during the process by relating the data to the processing positions in the process steps.

A plurality of steps exists in a photovoltaic element production process, as described above, and most of the steps include film formation in a film forming apparatus under a vacuum at a high temperature. In such a film formation step, there is a possibility that a film forming gas may turn around to an end portion of the surface of the substrate opposite to the film forming surface and attach to the surface end portion to form a film. In a case where film formation is performed while the substrate is continuously transported, there is a possibility that the surface (back surface) of the substrate may contact the film forming apparatus to occur a transport scratch that is parallel to the substrate transport direction (i.e., moving direction). Particularly, in a roll-to-roll system using a continuous substrate in a rolled form, the possibility of occurrence of such a transport scratch in the lengthwise direction of the substrate is high because the substrate is transported in a state of being strongly tensioned. If such a film attachment or transport scratch occurs on a mark given in the marking step for control of the production process, there is a possibility of failing to recognize the mark in the mark reading step. That is, a problem arises that the function of enabling control of the production process cannot be suitably performed due to the above-described factor that hinders reading of the mark.

Japanese Patent Application Laid-Open No. 2001-102604 has no description of any factor that hinders mark reading such as described above, and no description of any method of positively avoiding reading failure due to a factor that hinders mark reading. The publication includes a description of an error correcting function with respect to use of a two-dimensional code as a mark. However, the size of the mark is necessarily increased to effectively perform such an error correcting function using a two-dimensional code. Moreover, since the two-dimensional code itself is a mark that is complicated and needs to be precise, the time required to form such a mark is long. For this reason, it is difficult to accurately attach the two-dimensional code to the substrate surface in some cases of a process in which the substrate is continuously transported.

In the method disclosed in Japanese Patent Application Laid-Open No. H7-283431, a processing position on the continuous member is computed from the entire length of the continuous member, the amount of winding and a reference position. However, since the substrate itself has neither lot nor position information, there is a problem described below in the control of the production process.

That is, in a case where a continuous substrate is used in a process in which a photovoltaic element or the like is produced through a plurality of steps, there is a need for provision of a lead portion on the front end side of the substrate for loading in the apparatus in each step. The necessary length of this lead portion corresponds to the sum of the length of the apparatus and the length of a portion to be rolled around a bobbin. However, since it is difficult to accurately control this length every time the substrate is loaded, a nonnegligible error in the lead portion will occur at the time of transfer of the substrate between the steps.

FIG. 7 shows an example of a photovoltaic element production process using a continuous member in a rolled form. Step (A) is a step of cleaning a substrate; step (B) is a step of forming a film as a back surface electrode layer; each of steps (C) and (D) is a step of forming a film as a semiconductor layer; step (E) is a step of forming a film as a surface electrode layer; and step (F) is a step of cutting the substrate.

In the case of producing a photovoltaic element by using a continuous substrate in a rolled form, the front end and the rear end are changed and the film forming direction is reversed in every step, as shown in FIG. 7. Accordingly, lead portions are alternately generated at the substrate ends and the entire length of the substrate is reduced in each step. Therefore, it is seriously difficult to ensure that portions on which film formation is actually performed (available portions) coincide with each other with accuracy between the steps, and in actuality, film forming is performed by setting a margin of several meters on the front and rear sides of the available portion, so that the portion corresponding to this margin is wasted. Further, there is also a possibility that the position of the substrate may be dislocated between the steps and it is difficult to accurately control production conditions with respect to the substrate position.

Further, in a case where a continuous substrate having a length of one-roll such as several hundred meters is used, the time required for film forming is so long that the process may be stopped during the film formation due to an unexpected trouble such as instantaneous power failure or apparatus failure. In such a case, there is a case where a lot is divided into two by cutting a middle portion of the substrate or the substrate is extended by addition of a substrate as another lot by welding, depending on the condition of the substrate.

FIG. 8 shows an example of a production process of a case where the substrate (lot No. #01) is cut in the middle of film formation and a substrate in another lot (lot No. #02) is added thereto by welding in step (C) of FIG. 7. Since the entire length of the substrate is changed between the preceding and subsequent steps, and since the lot is also changed, substrate length management and lot management become very complicated. In such a situation, it is difficult to link the positions of the substrate in the rolled state and those of the sheet-shaped substrate pieces after cutting in step (F), and the substrate after cutting and the production conditions cannot be managed in accurate correspondence with each other.

### SUMMARY OF THE INVENTION

In order to resolve the above-described problems, the present invention provides a method of producing a substrate which ensures that the mark reading accuracy is not reduced even in a case where a factor that hinders reading of a mark, e.g., attachment of a film or scratch on the substrate surface is generated, and which can be adopted to management of a continuous substrate, and a mark reading program and a mark reading apparatus according to the method.

According to a first aspect of the present invention, there is provided a method of producing a substrate with a mark, comprising:

a marking step of forming a mark having an information (e.g., lot information or positional information) on a surface of a substrate; and

a reading step of reading the mark,

wherein prior to the reading step, at least a part of the mark is formed in a region of the substrate where a factor that hinders the reading of the mark in the reading step is not generated.

In the present invention, it is preferred that in the marking step, the mark is formed in a direction nonparallel to the direction of generation of the factor that hinders reading of the mark.

Further, it is preferred that in the marking step, the mark is formed in plurality such that the marking positions of at least two consecutive ones of the marks are offset with respect to each other in a direction perpendicular to the direction of generation of the factor that hinders reading of the marks.

Moreover, it is preferred that the factor that hinders reading of the mark is deformation of the substrate, film attachment to the substrate, a change in color of the substrate, or coloring of the substrate.

Further, it is preferred that in the marking step, the mark is formed while moving the substrate.

Moreover, it is preferred that in the reading step, a portion of the mark subjected to hindrance to reading due to the factor that hinders reading is inferred and implemented based on the result of reading of ones of the marks formed preceding and succeeding the formation of the mark subjected to the hindrance to reading.

Further, it is preferred that in the reading step, the mark is read while moving the substrate.

Moreover, it is preferred that the substrate is a continuous member.

Further, it is preferred that the method of producing the substrate is of a roll-to-roll system.

Moreover, it is preferred that the substrate is a non-light transmissive substrate.

Further, it is preferred that the substrate is a photovoltaic element substrate.

Moreover, it is preferred that the mark comprises a character, a bar code, a two-dimensional code, or a combination thereof.

Further, it is preferred that the mark is formed by laser, impression or printing.

According to a second aspect of the present invention, there is provided a mark reading program for reading marks formed on a surface of a substrate, the program making a computer execute:

a step of reading a plurality of marks;

a step of saving the results of reading of the marks as data;

a step of accessing data preceding and succeeding occurrence of a read error when the error occurs;

a step of comparing the accessed data with each other; and

a step of inferring and complementing data in which the data error has occurred on the basis of the result of the comparison.

According to a third aspect of the present invention, there is provided a mark reading apparatus for reading marks formed on a surface of a substrate, comprising:

means for reading marks;

means for saving the read marks as data; and

means for inferring and complementing, when a read error occurs, at least a portion, of data in which the data error has occurred on the basis of data stored by the means for saving preceding and succeeding the mark at which the read error has occurred.

### BRIEF DESCRIPTION OF THE DRAWINGS

FIG. 1 is a view showing a surface of a substrate with marks that is made by the production method in accordance with the present invention;

FIG. 2 is a view showing a state in which a portion of a mark made unreadable by hindrance to reaching is inferred and complemented from the results of reading of preceding and succeeding marks;

FIG. 3 is a view showing an example of a marking step;

FIG. 4 is a view showing an example of a mark-reading step;

FIG. 5 is a view showing a surface of a substrate with marks that is made by a conventional production method;

FIG. 6 is a view showing a surface of a substrate with marks that is made by a production method in accordance with the present invention;

FIG. 7 is a view showing an example of a process of producing a photovoltaic element using a continuous member substrate in a rolled form; and

FIG. 8 is a view showing an example of a case where a substrate is cut during the process of producing a photovoltaic element using a continuous member substrate in a rolled form.

### DESCRIPTION OF THE PREFERRED EMBODIMENTS

An embodiment of the present invention will be described.

FIG. 1 is a view showing a surface of a substrate produced by a production method in accordance with the present invention. FIG. 1 shows a state in which numbers of six figures, denoted by 102a, 102b, 102c and 102d, are formed as marks on a surface of a substrate 101, and in which factors 103 and 104 that hinder reading of these marks have been generated.

The marking method in accordance with the present invention comprises forming, prior to a reading step, at least a portion of a mark in a region of the surface where any factor that hinders reading of the mark in the reading step is not generated. Examples of factors that hinder reading are deformation of the substrate such as a transport scratch, attachment of a film to the substrate in a film formation step, a change in color of the substrate due to a heat treatment, coloring of the substrate by ink, etc., attachment of a foreign material to the substrate, or the like.

These factors of hindrance may be generated continuously through the entire substrate or only in a portion of the substrate. Film attachment due to going around of the gas to the back surface or the like is generated generally at a particular portion every time, so that the position of generation of film attachment can be predicted. However, since transport scratches occur depending generally on the conditions of the apparatus during substrate transportation, the position of occurrence of a transport scratch cannot be predicted at the time of marking on the substrate.

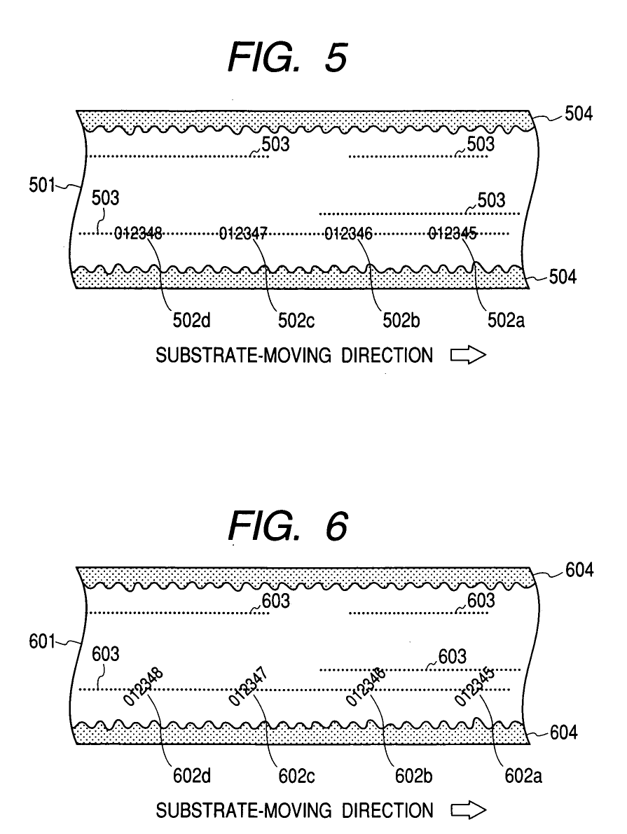

Generally, there is a large possibility that a factor of hindrance such as a transport scratch may be generated parallel to the substrate-moving direction because of the mechanism of its generation. In this case, as shown in FIG. 5 for example, where marks 502 are formed parallel to the direction of generation of the factor of hindrance, there is a possibility that a factor 503 of hindrance may be generated in a state of being superposed on the marks 502. In such a case, the factor 503 of hindrance extends through the whole of each mark 502. As a result, all the marks cannot be deciphered.

However, if marks are formed nonparallel to the direction of generation of a factor of hindrance as shown in FIG. 1, hindrance to reading can be limited so as to occur only on restricted portions of the marks.

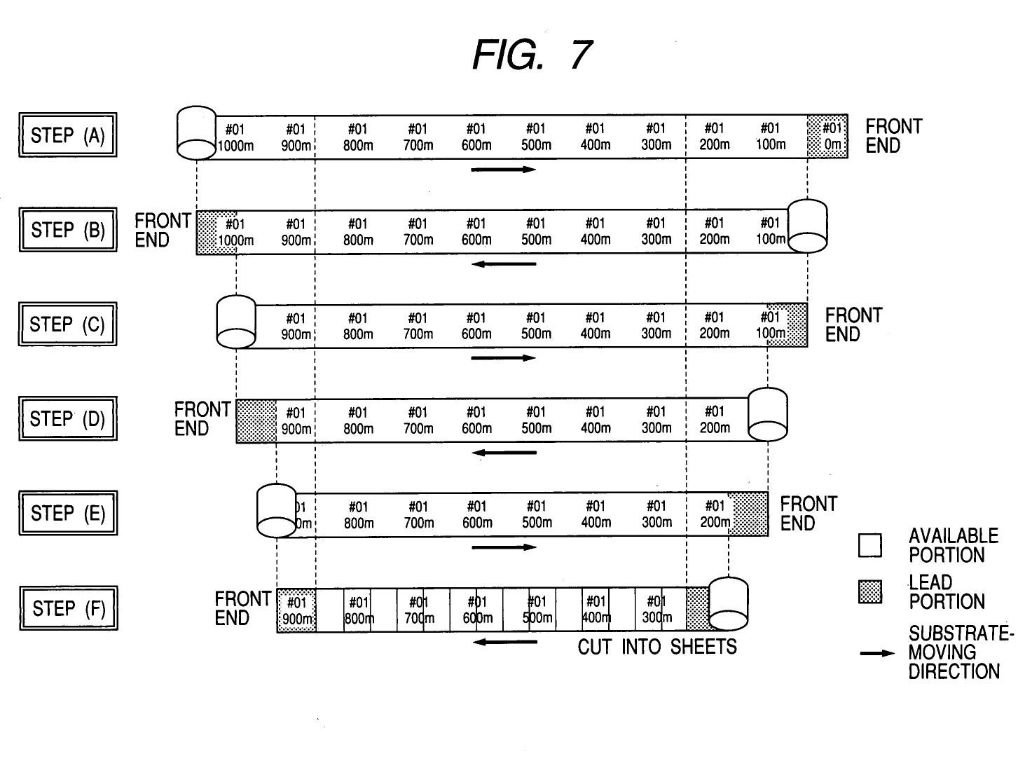

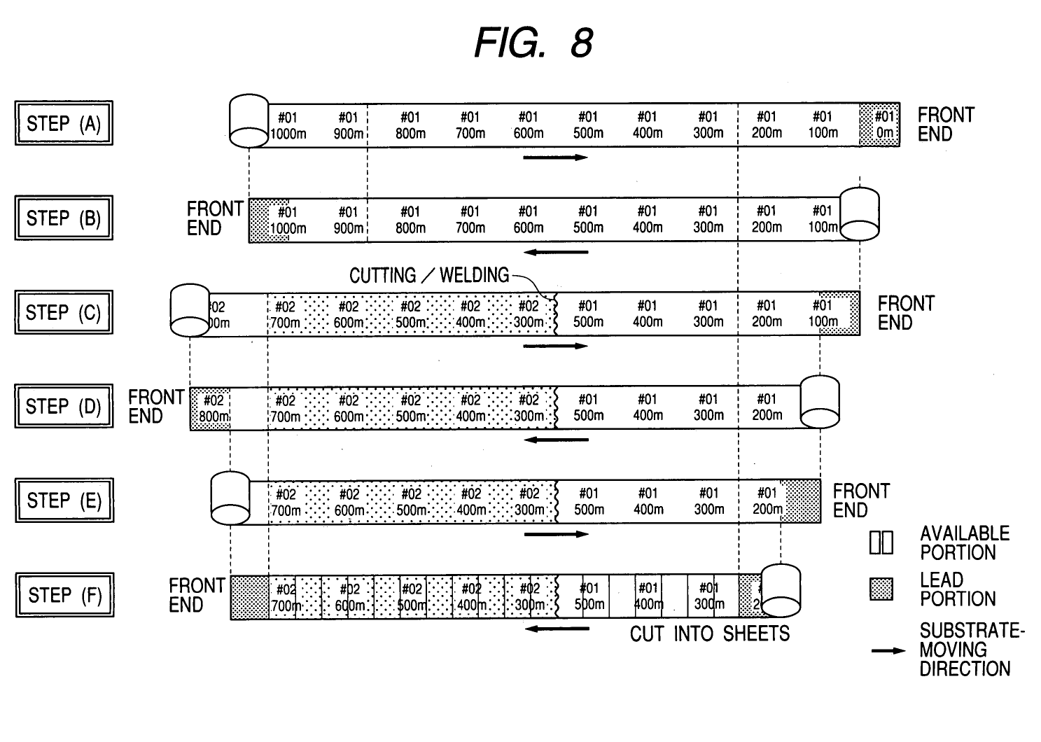

Further, in a case where marks are merely formed nonparallel to the direction of generation of a factor of hindrance as shown in FIG. 6 for example, there is a possibility that only the same, particular portion of each of the marks may become unreadable. In contrast, in a case where marks are formed such that the marking positions of consecutive two or more ones of the marks are offset with respect to each other in a direction perpendicular to the direction of generation of the factor of hindrance as shown in FIG. 1, the occurrence of an unreadable state of a particular portion of the marks can be effectively prevented.

That is, as shown in FIG. 1, by combining the method of forming marks non parallel to the direction of generation of a factor that hinders reading of the marks with the method of forming marks such that the marking positions of at least two consecutive ones of the marks, the location in mark of the portion made unreadable by hindrance to reading can be made different from each other between the consecutive marks.

In the case shown in FIG. 1, the first and fourth numerals “0” and “3” of the mark 102a, the sixth numeral “6” of the mark 102b, the second and third numerals “1” and “2” of the mark 102c and the fourth numeral “3” of the mark 102d are unreadable due to the factor 103 that hinders reading. Also, the first numeral “0” of the mark 102b is unreadable due to a factor 104 that hinders reading.

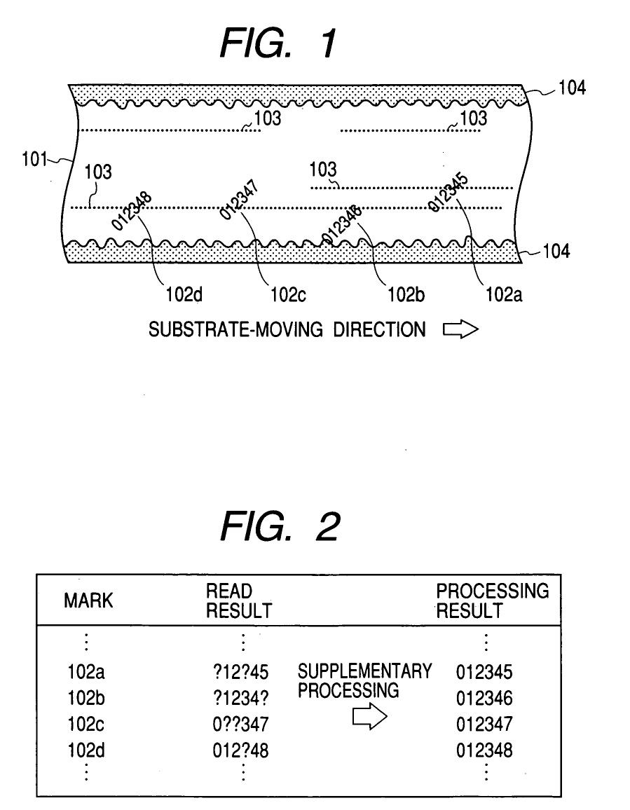

However, since the figures of the unreadable numerals differ from each other between consecutive ones of the marks, the portions made unreadable by hindrance to reading can be complemented by comparing the results of reading of consecutive ones of the marks, as shown in FIG. 2.

The angle of inclination of the marks to the direction of generation of a factor of hindrance and the amounts of offset of the marking positions are suitably determined depending on the size of the marks, the time required for marking, the substrate moving speed, the scale of the factor of hindrance, the frequency and the positions of generation of the factor of hindrance and the mark recognition rate of a reader. For example, in the case of using a laterally-extending mark such as a character sequence or a bar code, when the angle of inclination of the mark to the direction of generation of the factor of hindrance becomes closer to the right angle, the influence of one factor of hindrance is reduced but the possibility of a plurality of factors of hindrance influencing the mark is increased. Conversely, when the angle of inclination of the mark to the direction of generation of the factor of hindrance becomes closer to 0°, the influence of a plurality of factors of hindrance influencing the mark is reduced but hindrance to reading of the entire mark may occur due to only one factor.

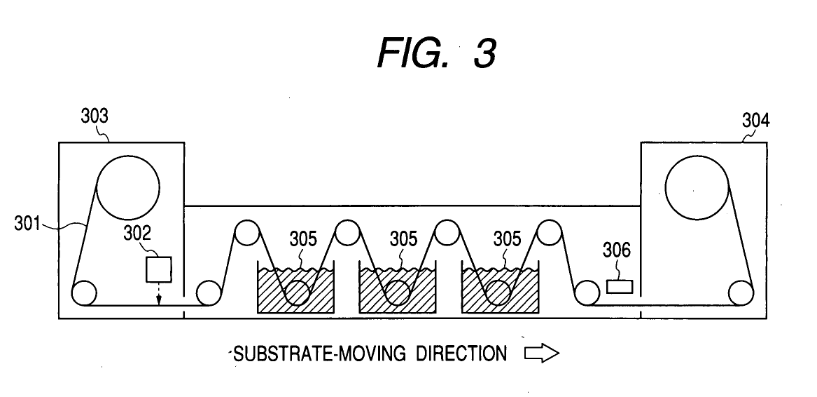

FIG. 3 is a view showing a marking step. In FIG. 3 are illustrated a continuous substrate 301, a marking device 302, an unwinding apparatus 303, a winding apparatus 304, cleaning baths 305 and a heater 306.

Marks are formed on a surface of the continuous substrate 301 by the marking device 302 while the continuous substrate 301 in a rolled state is transported. Sheet-shaped substrates may be provided instead of the continuous substrate and a single mark or a plurality of marks may be formed on each sheet-shaped substrate.

In a process of producing a photovoltaic element, it is desirable that the marking step be performed prior to a first film formation step. That is, it is desirable that in a case of using a non-light transmissive substrate, the marking step be performed prior to a step of forming a film as a back surface electrode layer and that in a case of using a light transmissive substrate, the marking step be performed prior to a step of forming a film as a front surface electrode layer.

The marking device 302 used in the marking step may be selected from various devices such as a laser marker, an impressing machine, a printing machine, or the like depending on the material, use and production conditions of the substrate. For marking on a photovoltaic element substrate, since such a substrate undergoes a step of forming a semiconductor film or the like after the marking step, a laser marker capable of performing marking at a high speed while preventing an impurity from entering a film may suitably be used.

As the laser markers, those which employ CO₂ laser, YAG laser, or the like as a laser species may be included. The YAG laser has a short wavelength of about 1/10 of that of CO₂ laser and therefore has a low reflectance on a metal surface and, hence, low energy loss. Therefore, in the case of marking on a metal substrate, the YAG layer is more suitable. On the contrary, the CO₂ laser has a wavelength within such a wavelength region (far infrared region) that its energy is absorbed in glass or the like, so that in the case of marking on a transparent member such as a glass member, the CO₂ laser is more suitable. As a method of marking with laser light, a scanning system or a masking system is used. If the contents of the marks to be formed change continuously as is the case with a product serial number, the scanning method is more suitable.

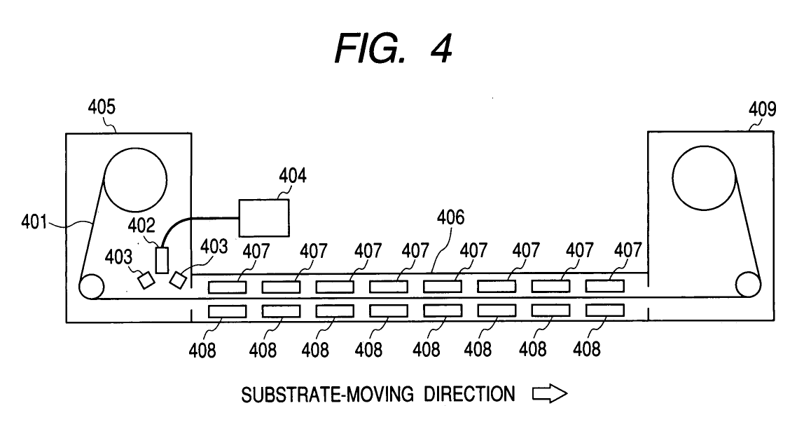

FIG. 4 is a view showing a mark-reading step. In FIG. 4 are illustrated a continuous substrate 401, a reader 402, a light emitting diode (LED) illuminator 403, an image processor 404, an unwinding apparatus 405, a film forming chamber 406, a heater 407, a target 408 and a winding apparatus 409.

The continuous substrate 401 in a rolled state is irradiated by illuminator 403 while being transported, and marks formed on a substrate at certain intervals are read with the reader 402. The results of reading are recorded together with the reading time and the data to production conditions. Also in this case, sheet-shaped substrates may be used instead of the continuous substrate.

While the reading step provided in a step of forming a film as a back surface electrode layer in the method of producing a photovoltaic element is shown in FIG. 4, the same reading step is also provided in each of film forming steps of forming a semiconductor layer and a front surface electrode layer. This makes it possible to record the history of putting the substrate into each film forming step (the time at which the substrate is put into the step, the lot number, the substrate position) and the data to the production conditions. The reading step may also be added to other steps as desired if there is a need for recording the input history of the substrate or the production condition data in those steps.

The reader 402 used in the reading step may be selected from an image processor such as a CCD camera using an image sensor, a bar code reader, a two-dimensional code reader, etc., according to kinds of marks. Usable kinds of marks include characters, a geometric figure, a bar code, a two-dimensional code, and the like.

If characters are used, the contents of a mark can easily be recognized even through visual observation. If simple characters such as alphanumeric characters are used, the time required for forming a mark can be reduced and it is possible to attach a mark even to an object moving at a high speed. On the other hand, in such a case, the amount of information per unit area is small and an image processor is required as the reader, resulting in an increase in apparatus cost.

It is necessary for a bar code or a two-dimensional code to be formed such that the shape of the mark is not deformed, for the reason relating to the characteristics of the mark. In the case of a two-dimensional code in particular, information is held therein in vertical and horizontal directions and, therefore, it is necessary to accurately form the mark without deformation or dislocation. If a laser marker is used as the marking device, a thick line of bar code needs to be depicted by laser application in a plurality of times, so that the time required for forming the mark is increased. For this reason, these marks are somewhat unsuitable for formation on an object moving at a high speed. In a case where the contrast of a mark is low as in the case of marking on a metal substrate, there is a possibility that reading failure may be generated only by use of a general-purpose bar code reader or two-dimensional code reader. However, if the amount of information contained in a mark itself is large and if a general-purpose reader can be used, the system can be constructed at a comparatively low cost.

Reading of marks is performed at equal time intervals or by triggering. Reading at equal time intervals is performed in such a manner that marks are read regardless of the existence of the mark in the field of view of a CCD and a read result is output only when the mark is recognized. For triggering, an external trigger or an internal trigger is used. The external trigger is such that the state of transport of the substrate is detected with an external sensor and a reading start signal is sent from the sensor to the reader when a mark printed on the substrate comes to a predetermined position on the reader. The internal trigger is such that at least a portion of a mark printed on the substrate is registered as a reference image in the reader and a reading start signal is generated when the reference image enters the field of view of the camera of the reader.

If there is a mark that could not be read or was erroneously read due to a factor of hindrance to reading, the portion of the mark subjected to hindrance to reading is inferred and complemented by comparing the results of reading of at least two consecutive marks. More specifically, complementation is performed by comparing the continuity of the read results and the printing history in the marking step with respect to those marks that precede and succeed the mark subjected to hindrance. In the case of a continuous substrate in particular, the continuity of marks in the same lot number is basically kept and, therefore, a portion of a mark subjected to hindrance to reading can be inferred from the results of reading preceding and succeeding the occurrence of a discontinuity even when the mark information is discontinuous at an intermediate position of the substrate as in the case of change of the lot number by addition of another substrate. Further, the reading accuracy itself can be improved by providing a checksum function in marks.

### EXAMPLES

Examples of the present invention will be described. However, the present invention is not limited to the examples described below.

### Example 1

In Example 1, a continuous substrate in a rolled form prepared by winding a thin stainless steel belt on a bobbin was used and a photovoltaic element was fabricated by performing steps (A) to (F) as shown in FIG. 7.

Step (A) is a step of cleaning a substrate; step (B) is a step of forming a film as a back surface electrode layer; each of steps (C) and (D) is a step of forming a film as a semiconductor layer; step (E) is a step of forming a film as a front surface electrode layer; and step (F) is a step of cutting the substrate. Although not described herein, there are further performed subsequent steps such as a cell forming step, a mounting step, and the like.

In step (A), the stainless steel substrate is cleaned by using a production apparatus such as shown in FIG. 3. Stainless steel substrate 301 unwound from the stainless roll set in the substrate unwinding apparatus 303 is passed through the cleaning baths 305, thereafter dried by the heater 306 and wound on a bobbin by the winding apparatus 304. The marking step in this example was performed immediately after unwinding of the substrate in step (A). The reason for performing the marking in this step is that this step is performed prior to the film forming step which is an important step in the production of the photovoltaic element for attaining the performance of the element; dust generated by marking can be removed in the cleaning baths 305; and the possibility of the apparatus being stopped due to unforeseen trouble is low because the cleaning step is comparatively simple in comparison with the subsequent steps and because the time required for this step is therefore short.

As the marking device, a scanning-type YAG laser marker was used because the member to which marking was performed was a stainless steel substrate and because the contents of marks to be printed were continuously changed.

Marking was performed at intervals of 1 m on the surface opposite from the photovoltaic element forming surface of the stainless steel substrate by the laser marker device 302. While marking was being performed, the stainless steel substrate was transported at a controlled, constant speed of 5000 mm/min by a rotary encoder provided on the winding apparatus side. The position on the substrate (the distance from a reference present at the front end of the substrate) was ascertained from the amount of winding of the substrate and a corresponding signal was sent to the laser maker device to perform marking.

As the contents of marks to be printed, numerals representing the lot number of the substrate and the positional information of the substrate are provided. The character size of the mark was 2 mm×1.5 mm, the mark forming direction was inclined at an angle of 45° to the substrate-moving direction, and the marking was performed with the marking start positions was randomly offset with respect to each other in the range of 20 mm to 50 mm from the substrate end (in the width direction).

On the stainless steel substrate subjected to the marking and the cleaning step, film formation of the back surface electrode layer was performed in step (B) by using a production apparatus such as shown in FIG. 4. Stainless steel substrate 401 unwound from the substrate unwinding apparatus 405 was again wound into a coil state by the winding apparatus 409 after film forming of the back surface electrode layer by sputtering in the film forming chamber 406, as with step (A).

In this example, a mark-reading step is provided in this step (B). More specifically, LED illuminator 403 and CCD camera 402 were provided close to and on the upstream side of the position at which the substrate entered the film forming chamber to pick up images while the substrate was being transported at 500 mm/min. The images were processed by the image processor 404. The results of reading of the marks were recorded in a database together with the times at which the marks were read. Simultaneously, the production process data in step (B) (the pressure in the film forming chamber, the temperature, the sputtering voltage and current, the flow rate of a film forming gas, etc.) were also recorded.

Thereafter, those portions that could not be read or were erroneously read were interred and complemented on the basis of comparison between preceding and succeeding read results and the printing history in the marking step.

Also, in the film forming steps, i.e., step (C), step (D) and step (E), a reading step was provided immediately before entrance of the substrate into the film-forming chamber, as with step (B) . Marks were read while the substrate was being transported at 500, 750, or 2500 mm/min in each film formation step. The results of reading of the marks were recorded in the database together with the times at which the marks were read and the production process data in each step were simultaneously recorded. Also, complementation or correction processing on the results of reading was performed, as in the case of process (B).

In step (F), the continuous substrate was cut by a width of 238.8 mm to form photovoltaic elements in the form of sheet-shaped cells. Product serial numbers were printed by ink jet printing individually on the sheet-shaped cells. Correlations with the lot number of the substrate and the positional information marks provided in the marking step (A) were obtained and saved in the database.

### Example 2

A photovoltaic element was produced by steps (A) to (F) such as shown in FIG. 7 following the same procedure as in Example 1 with the exception that the marking start positions in the photovoltaic element production method in Example 1 were fixed at positions of 40 mm from the substrate end (in the width) as shown in FIG. 6.

### Comparative Example 1

A photovoltaic element was produced by steps (A) to (F) such as shown in FIG. 7 following the same procedure as in Example 1 with the exception that the mark formation direction in the photovoltaic element production method in Example 1 was set to be parallel to the substrate-moving direction, and the marking start positions were fixed at positions of 40 mm from the substrate end (in the width direction) as shown in FIG. 5.

(Evaluation)

For the photovoltaic elements produced in the above-described examples and comparative example, the mark recognition rates in step (F) before and after the complementation processing of portions of marks in which transport scratches occurred were compared with each other. Table 1 shows the results of the comparison. The evaluation is effected such that a recognition rate of 90% or more is indicated by “AA”; a recognition rate of not. less than 70% but less than 90% is indicated by “A”; a recognition rate of not less than 50% but less than 70% is indicated by “B”; and a recognition rate of less than 50% was indicated by “C”. The term “recognition rate” as herein employed is defined by the following equation.

[Recognition rate (%)]=[Number of recognized (complemented) characters]/[Total number of printed characters]×100

TABLE 1

| | Before | After |
|---|---|---|
| | complementation | complementation |
| Example 1 | B | AA |
| Example 2 | B | A |
| Comparative | C | C |
| Example 1 | | |

As is seen from Table 1, 50% or more of the characters were recognized in each of Examples 1 and 2 even before complementation processing but only less than 50% of the characters were recognized in Comparative Example 1. The reason for the results is as described below. In Comparative Example 1, since the mark formation direction was parallel to the substrate-moving direction, a transport scratch acting as a factor of hindrance extended through the whole of some of the marks. In contrast, in the examples of the present invention, since the mark formation direction was not parallel to the substrate-moving direction, a transport scratch extends through only a part of some of the marks and recognition of the marks at other positions was still possible.

After complementation processing of the read results, the recognition rate in Example 1 was remarkably improved in comparison with that in Example 2. The reason for the result is as described below. In Example 1, since any consecutive two of the marks were different from each other in the location in mark of the portions made unreadable due to the factor of hindrance, the complementation processing was effectively functioned. On the other hand, in Example 2, since any consecutive two of the marks were identical to each other in the location in mark of the lost portions, the complementation effect was small. Therefore, Example 1 is more preferable embodiment.

On the other hand, in Comparative Example 1, the mark recognition rate was not substantially changed by performing complementation processing. This is because the amount of missing data at the stage of obtaining the read results before processing on which complementation processing was based was so large that the complementation processing was not effectively functioned.

As described in detail above, in the method of producing a substrate with marks, marks containing a substrate information such as a lot number of substrate or a substrate position information are formed in a particular region of the substrate in a continuous form for example, i.e., a region where any factor that hinders reading of the mark in the step of reading the mark is not generated, in the marking step prior to the reading step, and the marks are read in a subsequent step, thereby enabling the position of processing of the substrate to be easily controlled with accuracy and enabling grasping of a processing history of the substrate. Therefore, in particular, even in a case where a continuous substrate is subjected to cutting or substrate addition during a processing step, a case where the front and the rear ends of a continuous substrate are changed at the beginning of each step, or a case where a continuous substrate is cut into sheet-shaped substrates, production conditions or the like can easily be related to each other between the steps on the basis of information described on the substrate.

Especially, according to the present invention, a portion made unreadable due to a factor that hinders reading can be limited to only a part of each of marks by forming the marks nonparallel to the direction of generation of the factor that hinders reading. Further, when combined with the method of forming marks with the marking positions of at least two consecutive ones of the marks being offset with respect to each other in a direction perpendicular to the direction of generation of the factor of hindrance, the location in mark of the portion made unreadable by hindrance to reading can be made different from each other between consecutive marks. This marking method ensures that processing for complementation of the results of reading of consecutive marks can be performed by comparing the read results, thus improving the mark recognition rate.

What is claimed is:

1. A method of producing a substrate with a mark, comprising:
a marking step of forming a mark having an information on a surface of a substrate; and
a reading step of reading the mark,
wherein prior to the reading step, at least a part of the mark is formed in a region of the substrate where a factor that hinders the reading of the mark in the reading step is not generated.

2. The method according to claim 1, wherein in the marking step, the mark is formed in a direction nonparallel to the direction of generation of the factor that hinders reading of the mark.

3. The method according to claim 1, wherein in the marking step, the mark is formed in plurality such that the marking positions of at least two consecutive ones of the marks are offset with respect to each other in a direction perpendicular to the direction of generation of the factor that hinders reading of the marks.

4. The method according to claim 1, wherein the factor that hinders reading of the mark is deformation of the substrate.

5. The method according to claim 1, wherein the factor that hinders reading of the mark is film attachment to the substrate.

6. The method according to claim 1, wherein the factor that hinders reading of the mark is a change in color of the substrate.

7. The method according to claim 1, wherein the factor that hinders reading of the mark is coloring of the substrate.

8. The method according to claim 1, wherein in the marking step, the mark is formed while moving the substrate.

9. The method according to claim 1, wherein in the reading step, a portion of the mark subjected to hindrance to reading due to the factor that hinders reading of the mark is inferred and implemented based on the results of reading of ones of the marks formed preceding and succeeding the formation of the mark subjected to the hindrance to reading.

10. The method according to claim 1, wherein in the reading step, the mark is read while moving the substrate.

11. The method according to claim 1, wherein the substrate is a continuous member.

12. The method according to claim 1, which is of a roll-to-roll system.

13. The method according to claim 1, wherein the substrate is a non-light transmissive substrate.

14. The method according to claim 1, wherein the substrate is a photovoltaic element substrate.

15. The method according to claim 1, wherein the mark comprises a character, a bar code, a two-dimensional code or a combination thereof.

16. The method according to claim 1, wherein the mark is formed by a laser.

17. The method according to claim 1, wherein the mark is formed by impression.

18. The method according to claim 1, wherein the mark is formed by printing.

19. A mark reading program for reading marks formed on a surface of a substrate, the program making a computer execute:
a step of reading a plurality of marks;
a step of saving the results of reading of the marks as data;
a step of acessing data preceding and succeeding occurrence of a read error when the error occurs;
a step of comparing the accessed data with each other; and
a step of inferring and complementing data in which the data error has occurred on the basis of the result of the comparison.

20. A mark reading apparatus for reading marks formed on a surface of a substrate, comprising:
means for reading marks;
means for saving the read marks as data; and
means for inferring and complementing, when a read error occurs, at least a portion of data in which the data error has occurred on the basis of data stored by the means for saving preceding and succeeding the mark at which the read error has occurred.
